(19) United States
(12) Patent Application Publication
(10) Pub. No.: US 2025/0259919 A1
(43) Pub. Date: Aug. 14, 2025

(54) PACKAGE COMPRISING A SUBSTRATE AND A PASSIVE DEVICE

(71) Applicant: QUALCOMM Incorporated, San Diego, CA (US)

(72) Inventors: Aniket PATIL, San Diego, CA (US); Manuel ALDRETE, Encinitas, CA (US); Piyush GUPTA, San Diego, CA (US)

(21) Appl. No.: 18/439,360

(22) Filed: Feb. 12, 2024

(51) Int. Cl. H01L 23/498; H01L 21/48; H01L 23/495

(52) U.S. Cl. CPC H01L 23/49816; H01L 21/4853; H01L 21/486; H01L 23/49589; H01L 23/49827

(57) ABSTRACT

A package comprising a substrate comprising a first surface and a second surface, wherein the substrate further comprises: at least one dielectric layer; and a plurality of interconnects; an integrated device coupled to the first surface of the substrate through at least a first plurality of solder interconnects; and a passive device coupled to the second surface of the substrate through at least a second plurality of solder interconnects, wherein the passive device comprises at least one through substrate via.

### FIELD

Various features relate to packages with a substrate and a passive device.

### BACKGROUND

A package may include a substrate and integrated devices. These components are coupled together to provide a package that may perform various electrical functions. There is an ongoing need to provide better performing packages. Moreover, there is also an ongoing need to reduce the overall size of the packages.

### SUMMARY

Various features relate to packages with a substrate and a passive device.

One example provides a package comprising a substrate comprising a first surface and a second surface, wherein the substrate further comprises: at least one dielectric layer; and a plurality of interconnects; an integrated device coupled to the first surface of the substrate through at least a first plurality of solder interconnects; and a passive device coupled to the second surface of the substrate through at least a second plurality of solder interconnects, wherein the passive device comprises at least one through substrate via.

Another example provides a method for fabricating a package. The method provides a substrate comprising a first surface and a second surface, wherein the substrate further comprises: at least one dielectric layer; and a plurality of interconnects. The method couples an integrated device to the first surface of the substrate through at least a first plurality of solder interconnects. The method couples a passive device to the second surface of the substrate through at least a second plurality of solder interconnects, wherein the passive device comprises at least one through substrate via.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a substrates and a passive device.

FIG. 2 illustrates an exemplary cross sectional profile view of a trench capacitor device.

FIG. 3 illustrates an exemplary cross sectional plan view of a package that includes a substrate and a passive device.

FIG. 4 illustrates an exemplary cross sectional plan view of a package that includes a substrate and a passive device.

FIG. 5 illustrates an exemplary cross sectional profile view of an integrated device.

FIGS. 6A-6D illustrate an exemplary sequence for fabricating a trench capacitor device.

FIG. 7 illustrates an exemplary flow chart of a method for fabricating a trench capacitor device.

FIGS. 8A-8B illustrate an exemplary sequence for fabricating a package that includes a substrate and a passive device.

FIG. 9 illustrates an exemplary flow chart of a method for fabricating a package that includes a substrate and a passive device.

FIGS. 10A-10B illustrate an exemplary sequence for fabricating a substrate.

FIG. 11 illustrates an exemplary flow chart of a method for fabricating a substrate.

FIG. 12 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure a package comprising a substrate comprising a first surface and a second surface, wherein the substrate further comprises: at least one dielectric layer; and a plurality of interconnects. The package also includes an integrated device coupled to the first surface of the substrate through at least a first plurality of solder interconnects; and a passive device coupled to the second surface of the substrate through at least a second plurality of solder interconnects, wherein the passive device comprises at least one through substrate via. As will be further described below, the package provides improved, efficient and/or effective electrical connections in a compact form factor, while also providing a more structurally robust and stable package.

### Exemplary Package Comprising a Substrate and a Passive Device

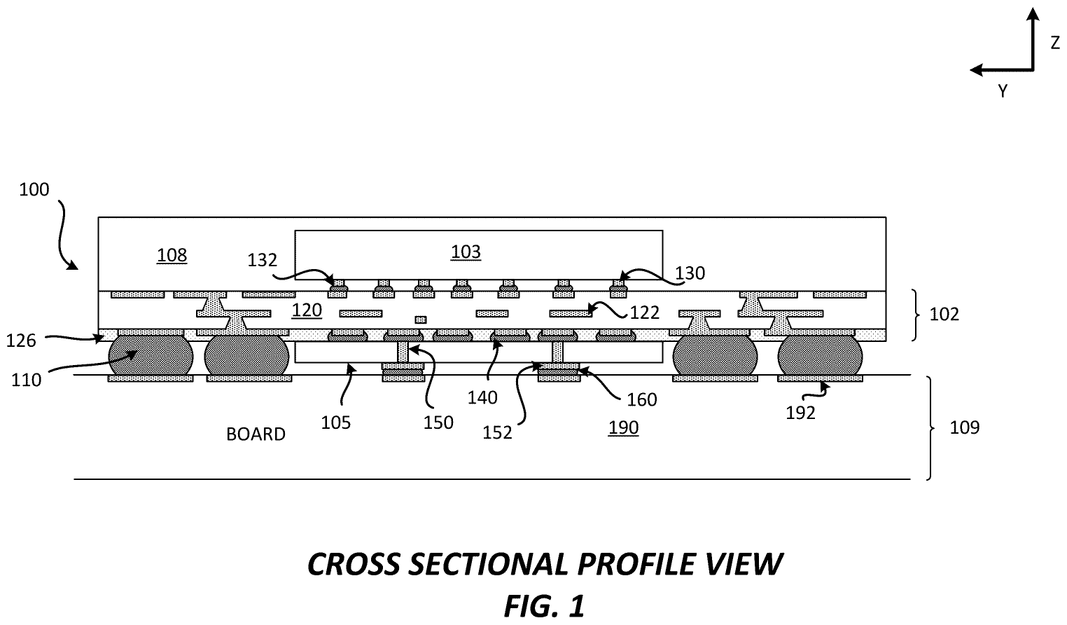

FIG. 1 illustrates a cross sectional profile view of a package 100 that includes a substrate and a passive device. The package 100 is coupled to a board 109 through a plurality of solder interconnects 110. The board 109 includes at least one board dielectric layer 190 and a plurality of board interconnects 192. The board 109 may include a printed circuit board (PCB).

The package 100 includes a substrate 102, an integrated device 103, a passive device 105 and an encapsulation layer 106. The substrate 102 includes at least one dielectric layer 120, a plurality of interconnects 122, and a solder resist layer 126. The at least one dielectric layer 120 may include at least one first dielectric layer. The plurality of interconnects 122 may include a first plurality of interconnects. The substrate 102 may include a first surface (e.g., top surface) and a second surface (e.g., bottom surface). The second surface may be opposite to the first surface.

The integrated device 103 may be a first integrated device. The integrated device 103 may be coupled to the substrate 102 through a plurality of pillar interconnects 130 and a plurality of solder interconnects 132. The integrated device 103 may be coupled to the first surface (e.g., top surface) of the substrate 102 through a plurality of pillar interconnects 130 and a plurality of solder interconnects 132. The integrated device 103 may be coupled to the interconnects from the plurality of interconnects 122 through the plurality of pillar interconnects 130 and the plurality of solder interconnects 132. The plurality of solder interconnects 132 are touching interconnects from the plurality of interconnects 122. The integrated device 103 may include a front side and a back side.

The passive device 105 is coupled to the substrate 102 through a plurality of solder interconnects 140. For example, the passive device 105 may be coupled to the second surface (e.g., bottom surface) of the substrate 102 through the plurality of solder interconnects 140. The plurality of solder interconnects 140 may be coupled to interconnects from the plurality of interconnects 122 of the substrate 102.

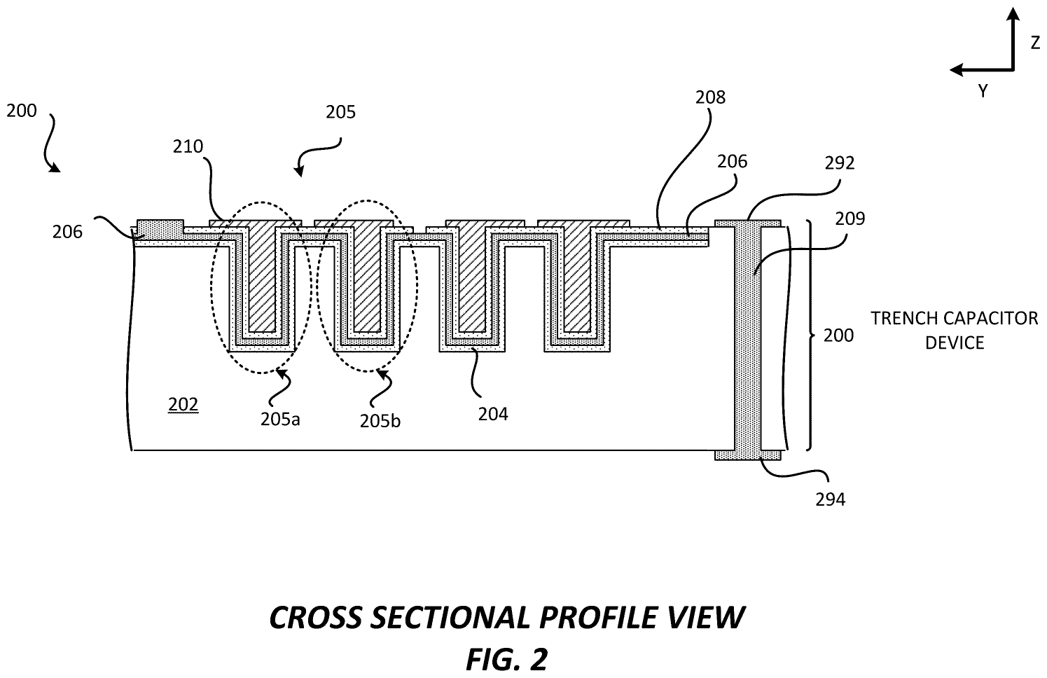

The passive device 105 may include a plurality of through substrate vias 150. The passive device 105 may also include a plurality of metallization interconnects 152. The plurality of metallization interconnects 152 may be coupled to the plurality of through substrate vias 150. The plurality of metallization interconnects 152 may be coupled to a surface of the passive device 105. The plurality of metallization interconnects 152 may be a plurality of back side metallization interconnects. As will be further described below in at least FIG. 2, the passive device 105 may include a passive device substrate, a plurality of trench capacitors (e.g., deep trench capacitors), at least one through substrate via and a metallization portion coupled to a surface of the passive device substrate. The passive device 105 may be configured as a trench capacitor device (e.g., deep trench capacitor device). The passive device 105 may be part of a power distribution network. Some of the interconnects from the passive device 105 may be configured as an electrical path for power. Some of the interconnects from the passive device 105 may be configured as an electrical path for signals to and/or from the integrated device 103.

The plurality of through substrate vias 150 may be coupled to the plurality of solder interconnects 140. In some implementations, there may be a plurality of metallization interconnects (e.g., a plurality of front side metallization interconnects). between the plurality of solder interconnects 140 and the plurality of through substrate vias 150. Thus, in some implementations, the plurality of solder interconnects 140 may be coupled to and touch a plurality of front side metallization interconnects. The passive device 105 may be coupled to the board 109 through a plurality of solder interconnects 160. The plurality of solder interconnects 160 may be coupled to and touch the plurality of metallization interconnects 152. In some implementations, the plurality of solder interconnects 160 may be coupled to and touch the plurality of through substrate vias 150.

The encapsulation layer 108 is coupled to the first surface of the substrate 102. The encapsulation layer 108 may at least partially encapsulate the integrated device 103. The encapsulation layer 108 may touch the substrate 102 and the integrated device 103. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

An electrical path between the integrated device 103 and the board 109 may include (i) a pillar interconnect from the plurality of pillar interconnects 130, (ii) a solder interconnect from the plurality of solder interconnects 132, (iii) at least one interconnect from the plurality of interconnects 122, (iv) a solder interconnect from the plurality of solder interconnects 110, and/or (iv) at least one board interconnect from the plurality of board interconnects 192.

An electrical path between the integrated device 103 and the board 109 may include (i) a pillar interconnect from the plurality of pillar interconnects 130, (ii) a solder interconnect from the plurality of solder interconnects 132, (iii) at least one interconnect from the plurality of interconnects 122, (iv) a solder interconnect from the plurality of solder interconnects 140, (iv) the passive device 105, (v) a solder interconnect from the plurality of solder interconnects 160 and/or (vi) at least one board interconnect from the plurality of board interconnects 192.

An electrical path between the integrated device 103 and the board 109 may include (i) a pillar interconnect from the plurality of pillar interconnects 130, (ii) a solder interconnect from the plurality of solder interconnects 132, (iii) at least one interconnect from the plurality of interconnects 122, (iv) a solder interconnect from the plurality of solder interconnects 140, (iv) a through substrate via from the plurality of through substrate vias 150, (v) a solder interconnect from the plurality of solder interconnects 160 and/or (vi) at least one board interconnect from the plurality of board interconnects 192.

An electrical path between the integrated device 103 and the board 109 may include (i) a pillar interconnect from the plurality of pillar interconnects 130, (ii) a solder interconnect from the plurality of solder interconnects 132, (iii) at least one interconnect from the plurality of interconnects 122, (iv) a solder interconnect from the plurality of solder interconnects 140, (iv) a through substrate via from the plurality of through substrate vias 150, (v) a metallization interconnect from the plurality of metallization interconnects 152, (vi) a solder interconnect from the plurality of solder interconnects 160 and/or (vii) at least one board interconnect from the plurality of board interconnects 192.

The use of the passive device 105 with through substrate vias help improve the performance of the package 100. One, the passive device 105 allows more ball count (e.g., more solder interconnects) between the package and the board, which means more electrical connections between the package and the board with the same package size. Two, a larger passive device may be used, which may help decrease the stress risk on the passive device. Three, coupling the passive device 105 to the board 109 helps provide additional structural support for the package, which helps improve the structural robustness of the package. Four, the through substrate vias provide a thermal path for heat dissipation from the integrated device 103 and/or the passive device 105, which can help improve the performance of the package 100.

### Exemplary Device/Chiplet with Deep Trench Capacitors

FIG. 2 illustrates a cross sectional profile view of a chiplet 200 that is configured as a trench capacitor device. The chiplet 200 may be an integrated passive device (e.g., passive device) that includes multiple trench capacitors (e.g., deep trench capacitors). The chiplet 200 may be a means for trench capacitance. The chiplet 200 may represent the passive device 105. The chiplet 200 includes a front side and a back side.

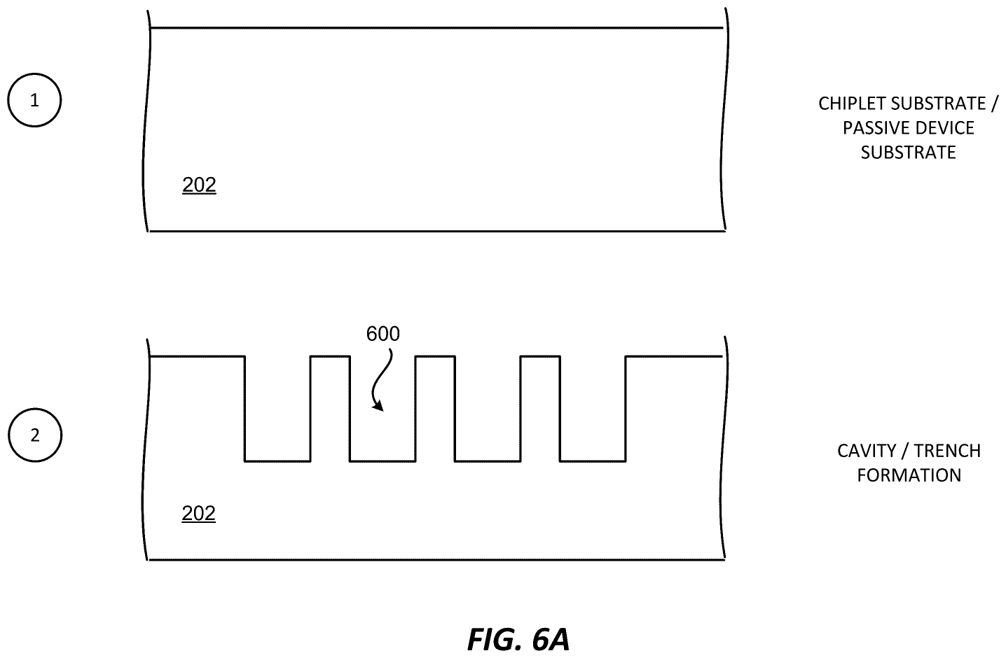

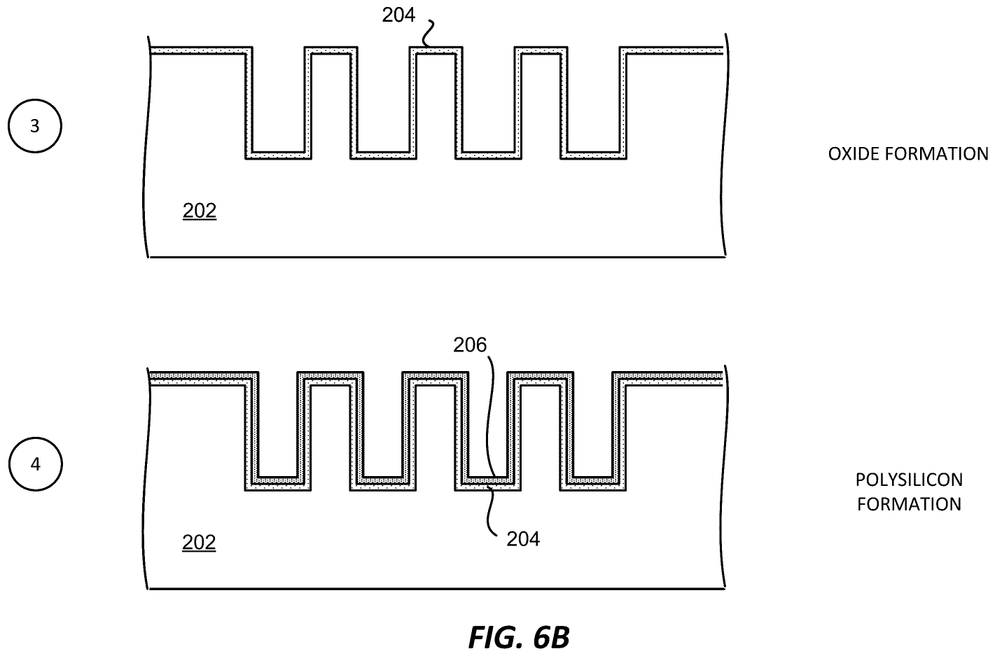

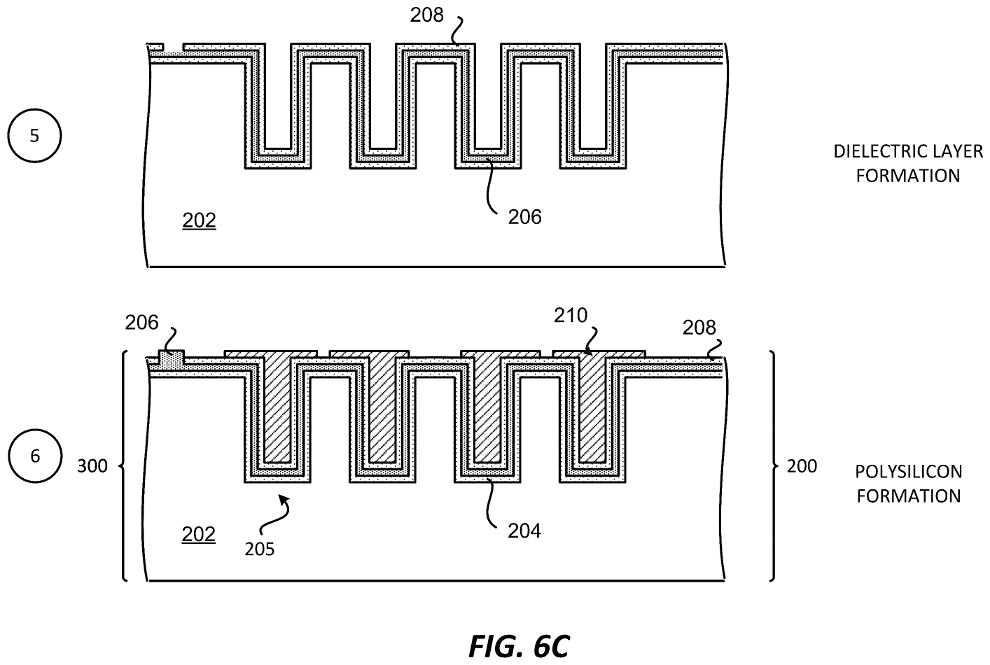

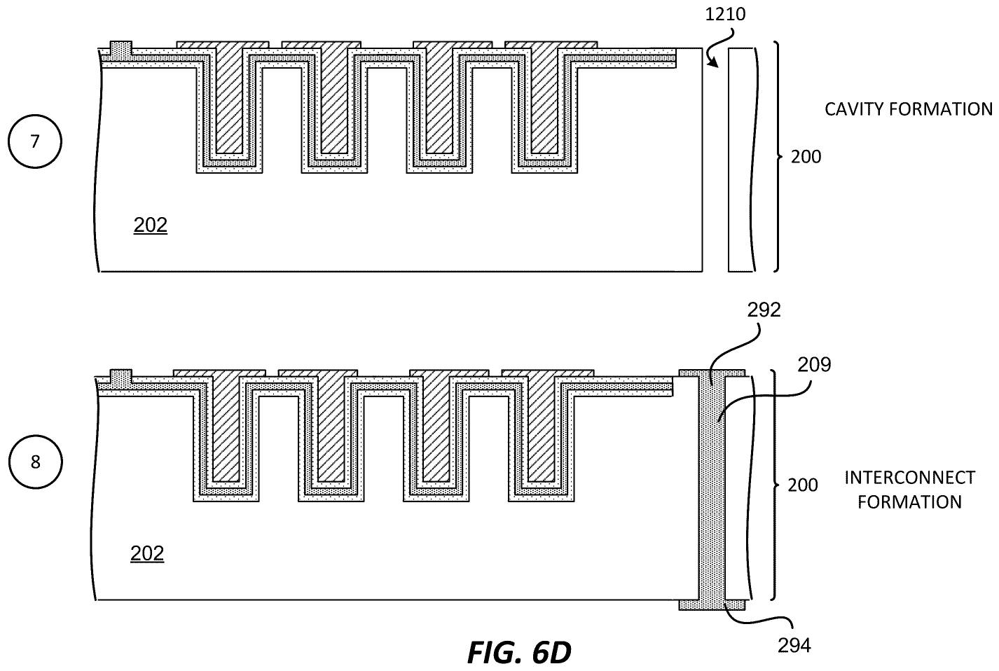

The front side of the chiplet 200 may include the plurality of trench capacitors. The chiplet 200 includes a chiplet substrate 202 (e.g., passive device substrate) and a plurality of trench capacitors 205. A plurality of solder interconnects (not shown) may be coupled to the chiplet 200. The chiplet substrate 202 may include silicon (Si). The chiplet substrate 202 may include a plurality of trenches and/or cavities over which capacitors may be formed. Examples of trenches and/or cavities are further described below in at least FIGS. 6A-6D.

The plurality of trench capacitors 205 includes a trench capacitor 205a and a trench capacitor 205b. The trench capacitor 205a and the trench capacitor 205b may be configured to be part of a same capacitor (e.g., first capacitor, first trench capacitor). The trench capacitor 205a and the trench capacitor 205b may be configured to be coupled to and/or part of a first power distribution network (PDN). The trench capacitor 205a and the trench capacitor 205b may be configured to be part of a first electrical path for a first power for a package. The trench capacitor 205a and the trench capacitor 205b may be configured to be coupled to integrated device(s).

As shown in FIG. 2, the chiplet 200 includes the chiplet substrate 202, an oxide layer 204, a first electrically conductive layer 206, a dielectric layer 208, and a second electrically conductive layer 210. The first electrically conductive layer 206 and/or the second electrically conductive layer 210 may include polysilicon. The oxide layer 204 and/or the dielectric layer 208 may include SiO₂ (e.g., low-pressure chemical vapor deposition (LPCVD) SiO₂) or Si₃N₄ (e.g., LPCVD Si₃N₄). Portions of the oxide layer 204, the first electrically conductive layer 206, the dielectric layer 208, and the second electrically conductive layer 210 may be located in trenches and/or cavities of the chiplet substrate 202. It is noted that a chiplet substrate 202 may be considered to have a trench or a cavity, even if the trench or the cavity is filled with one or more materials.

The trench capacitor 205a (e.g., first trench capacitor, first capacitor, means for first trench capacitance) may be defined by (i) a first portion of the oxide layer 204, (ii) a first portion of the first electrically conductive layer 206, (iii) a first portion of the dielectric layer 208, and (iv) a first portion of the second electrically conductive layer 210 that are located in a trench (e.g., first trench) of the chiplet substrate 202.

The trench capacitor 205b (e.g., second trench capacitor, second capacitor, means for second trench capacitance) may be defined by (i) a second portion of the oxide layer 204, (ii) a second portion of the first electrically conductive layer 206, (iii) a second portion of the dielectric layer 208, and (iv) a second portion of the second electrically conductive layer 210 that are located in a trench (e.g., second trench) of the chiplet substrate 202. It is noted that trench capacitor 205b may be part of a same capacitor as the trench capacitor 205a. That is, the trench capacitor 205a and the trench capacitor 205b may be configured to be electrically coupled together to form a capacitor (e.g., first capacitor) with a greater capacitance.

The chiplet 200 also includes an interconnect 209, an interconnect 292 and an interconnect 294. The interconnect 209 is coupled to the interconnect 292 and the interconnect 294. The interconnect 209 may be a through substrate via that extends through the chiplet substrate 202. The interconnect 292 may be a pad interconnect. The interconnect 294 may be a pad interconnect. The interconnect 292 may be located on the front side of the chiplet 200. The interconnect 292 may be located on the back side of the chiplet 200. The interconnect 209 may be a through chiplet substrate interconnect. The chiplet may include at least one through chiplet substrate interconnect. The interconnect 292 may be part of a plurality of metallization interconnects (e.g., plurality of front side metallization interconnects). The interconnect 294 may be part of a plurality of metallization interconnects (e.g., plurality of back side metallization interconnects).

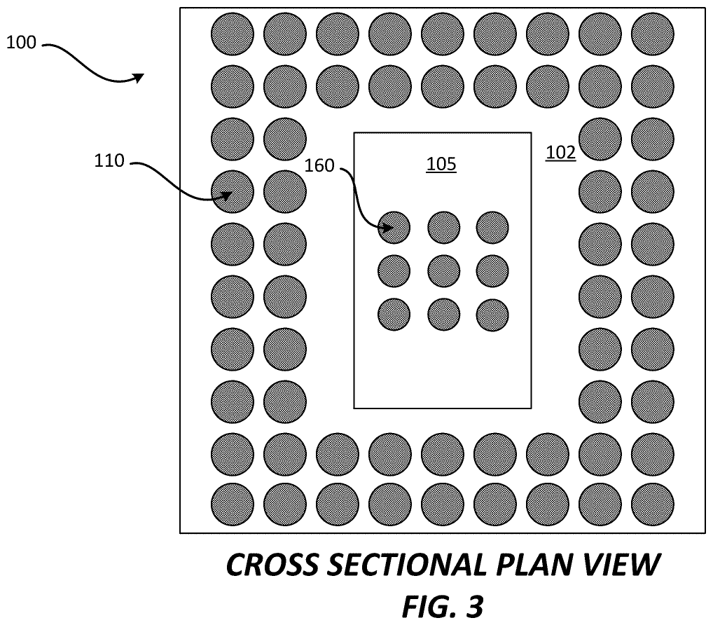

FIG. 3 illustrates an exemplary plan view of the package 100 that includes the substrate 102, the passive device 105, the plurality of solder interconnects 110 and the plurality of solder interconnects 160. The exemplary plan view of FIG. 3, may be a bottom plan view of the package 100. The package 100 is configured to be coupled to a board 109. The plurality of solder interconnects 110 are coupled to and touch the substrate 102 and the board 109. The plurality of solder interconnects 160 are coupled to and touch the passive device 105 and the board 109. The plurality of solder interconnects 160 are part of an electrical path that extends through the passive device 105. The plurality of solder interconnects 160 are configured to help provide structural support for the passive device 105 and the package 100. FIG. 3 illustrates one example of a configuration and/or arrangement of the plurality of solder interconnects 160. However, different implementations may have different numbers of solder interconnects for the plurality of solder interconnects 160, different configurations of solder interconnects for the plurality of solder interconnects 160 and/or different arrangements of the solder interconnects for the plurality of solder interconnects 160.

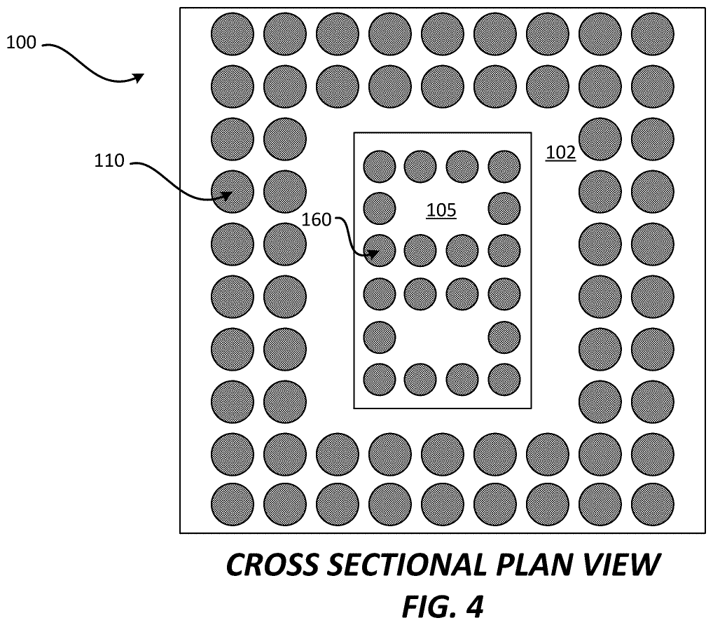

FIG. 4 illustrates an exemplary plan view of the package 100 that includes the substrate 102, the passive device 105, the plurality of solder interconnects 110 and the plurality of solder interconnects 160. FIG. 4 illustrates a different arrangement of the plurality of solder interconnects 160. The exemplary plan view of FIG. 4, may be a bottom plan view of the package 100. The package 100 is configured to be coupled to a board 109. The plurality of solder interconnects 110 are coupled to and touch the substrate 102 and the board 109. The plurality of solder interconnects 160 are coupled to and touch the passive device 105 and the board 109. The plurality of solder interconnects 160 are part of an electrical path that extends through the passive device 105. The plurality of solder interconnects 160 are configured to help provide structural support for the passive device 105 and the package 100.

### Exemplary Integrated Device

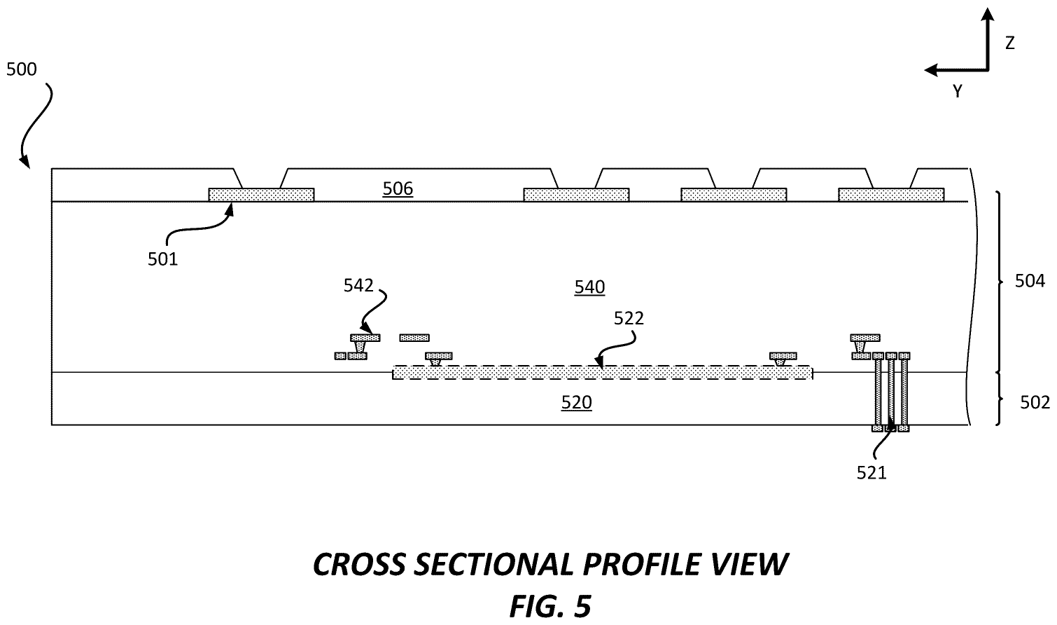

FIG. 5 illustrates a cross sectional profile view of an integrated device 500 that includes a die substrate. The integrated device 500 may represent the integrated device 103. The integrated device 500 includes a die substrate portion 502 and a die interconnection portion 504. The die substrate portion 502 includes a die substrate 520, an active region 522 and a plurality of through substrate vias 521. The active region 522 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 522 of the die substrate 520.

The die substrate 520 may include silicon (Si). The die substrate 520 may comprise a bulk silicon. The bulk silicon may include a monolith silicon. The plurality of through substrate vias 521 may extend through the die substrate 520. Different implementations may have different thicknesses for the die substrate 520. A back side metallization portion comprising a plurality of metallization interconnects may be coupled to the back side of the die substrate 520. The plurality of metallization interconnects may be coupled to the plurality of through substrate vias 521.

The die interconnection portion 504 includes at least one dielectric layer 540 and a plurality of die interconnects 542. The die interconnection portion 504 is coupled to the die substrate portion 502. The plurality of die interconnects 542 is coupled to the active region 522 of the die substrate portion 502. The plurality of die interconnects 542 may be coupled to the plurality of through substrate vias 521. The die interconnection portion 504 may also include a plurality of pad interconnects 501 and a passivation layer 506. In some implementations, a back end of line (BEOL) process may be used to fabricate the die interconnection portion 504.

In some implementations, an electrical path to and/or from an active region 522 may include at least one die interconnect from the plurality of die interconnects 542, at least one through substrate via from the plurality of through substrate vias 521. In some implementations, an electrical path to and/or from an active region 522 may include at least one die interconnect from the plurality of die interconnects 542, at least one pad interconnect from the plurality of pad interconnects 501.

An integrated device (e.g., 103) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advance technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G). The packages (e.g., 100, 300, 400) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

Having described various packages, a sequence for fabricating a package will now be described below.

### Exemplary Sequence for Fabricating a Chiplet with Trench Capacitors

In some implementations, fabricating a chiplet with trench capacitors includes several processes. FIGS. 6A-6D illustrate an exemplary sequence for providing or fabricating a chiplet with trench capacitors. In some implementations, the sequence of FIGS. 6A-6D may be used to provide or fabricate the chiplet 200 of FIG. 2. However, the process of FIGS. 6A-6D may be used to fabricate any of the chiplets described in the disclosure and/or the passive device 105.

It should be noted that the sequence of FIGS. 6A-6D may combine one or more stages in order to simplify and/or clarify the sequence for providing or fabricating a chiplet with trench capacitors. In some implementations, the order of the processes may be changed or modified. In some implementations, one or more of processes may be replaced or substituted without departing from the scope of the disclosure.

Stage 1, as shown in FIG. 6A, illustrates a state after a substrate 202 is provided. The substrate 202 may be a chiplet substrate. The substrate 202 may include silicon (Si).

Stage 2 illustrates a state after a plurality of trenches 600 is formed in the substrate 202. The plurality of trenches 600 may include a plurality of cavities. The plurality of trenches 600 may include a first trench, a second trench, a third trench, and a fourth trench. The trenches may have different shapes and/or different depths. An etching process may be used to form the plurality of trenches. The plurality of trenches 600 may be evenly spaced or have different spacing.

Stage 3, as shown in FIG. 6B, illustrates a state after an oxide layer 204 is formed over a surface of the substrate 202. A deposition process may be used to form the oxide layer 204 over the surface of the substrate 202 including over and in the plurality of trenches 600. For example, a chemical vapor deposition (CVD) process may be used to form the oxide layer 204. A low-pressure chemical vapor deposition (LPCVD) process may be used to form the oxide layer 204. The oxide layer 204 may take up the shape and/or contour of the plurality of trenches 600.

Stage 4 illustrates a state after a first electrically conductive layer 206 is formed over the oxide layer 204. The first electrically conductive layer 206 may include polysilicon. A deposition process may be used to form the first electrically conductive layer 206 over the oxide layer 204 including over and in the plurality of trenches 600. For example, a chemical vapor deposition (CVD) process may be used to form the first electrically conductive layer 206. A low-pressure chemical vapor deposition (LPCVD) process may be used to form the first electrically conductive layer 206. The first electrically conductive layer 206 may take up the shape and/or the contour of the oxide layer 204 and/or the plurality of trenches 600. The first electrically conductive layer 206 may include polysilicon. The first electrically conductive layer 206 may be doped. An example of a dopant includes boron. Thus, for example, the first electrically conductive layer 206 may include a LPCVD polysilicon doped with boron.

Stage 5, as shown in FIG. 6C, illustrates a state after a dielectric layer 208 is formed over the first electrically conductive layer 206. A deposition process and/or a lamination process may be used to form the dielectric layer 208 over the first electrically conductive layer 206 including over and in the plurality of trenches 600.

Stage 6 illustrates a state after a second electrically conductive layer 210 is formed over the dielectric layer 208. The second electrically conductive layer 210 may include polysilicon. A deposition process may be used to form the second electrically conductive layer 210 over the dielectric layer 208 including over and in the plurality of trenches 600. For example, a chemical vapor deposition (CVD) process may be used to form the second electrically conductive layer 210. A low-pressure chemical vapor deposition (LPCVD) process may be used to form the second electrically conductive layer 210. An etching process may be used to form the various portions of the second electrically conductive layer 210. The second electrically conductive layer 210 may fill up the plurality of trenches 600. The second electrically conductive layer 210 may be doped. An example of a dopant includes boron. Thus, for example, the second electrically conductive layer 210 may include a LPCVD polysilicon doped with boron. Stage 6 may also illustrate where additional portion(s) of the first electrically conductive layer 206 may be formed. The additional portion(s) of the first electrically conductive layer 206 may be formed through opening(s) of the dielectric layer 208. The additional portion(s) of the first electrically conductive layer 206 that is not covered by the dielectric layer 208 may be used as a pad to be coupled to a solder interconnect. The additional portion of the first electrically conductive layer 206 may be formed using a deposition process. The first electrically conductive layer 206 and/or the second electrically conductive layer 210 may include polysilicon.

Stage 7, as shown in FIG. 6D, illustrates a state after at least one cavity 610 is formed in the substrate 202. An etching process and/or a laser process (e.g., laser ablation) may be used to form the at least one cavity 610 that extends through the entire thickness of the substrate 202.

Stage 8 illustrates a state after the interconnect 209, the interconnect 292 and the interconnect 294 are formed. A plating process may be used to form the interconnect 209, the interconnect 292 and the interconnect 294. Stage 8 illustrates an example of the chiplet 200 that includes a plurality of trench capacitors 205.

### Exemplary Flow Diagram of a Method for Fabricating a Chiplet with Deep Trench Capacitors

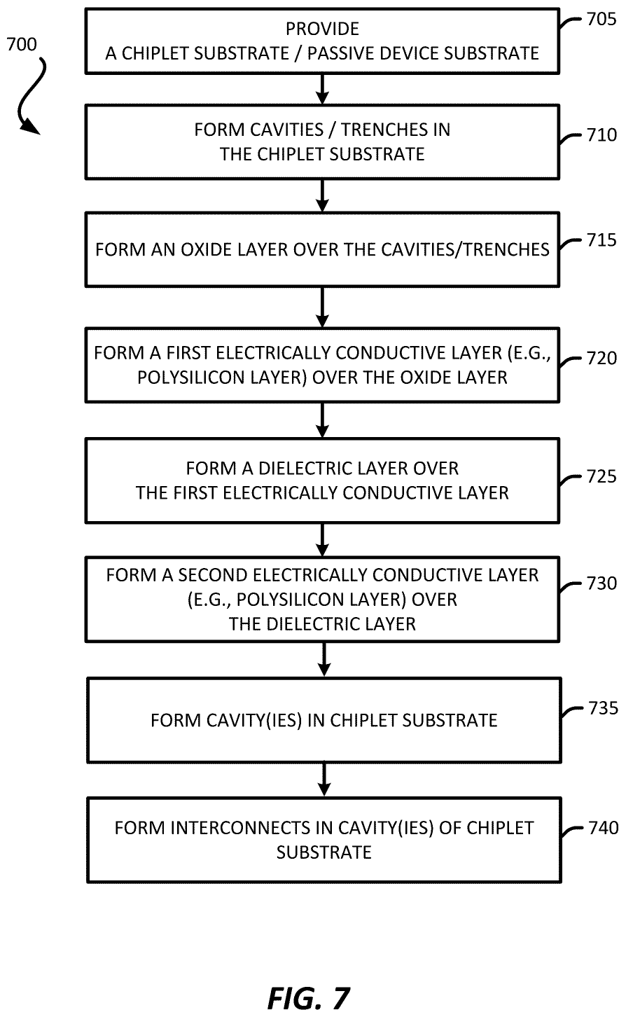

In some implementations, fabricating chiplet with trench capacitors includes several processes. FIG. 7 illustrates an exemplary flow diagram of a method 700 for providing or fabricating a chiplet with trench capacitors. In some implementations, the method 700 of FIG. 7 may be used to provide or fabricate the chiplet 200 of FIG. 2. However, the method 700 may be used to fabricate any chiplet with trench capacitors. The method 700 of FIG. 7 will be used to describe fabricating the chiplet 200.

It should be noted that the method of FIG. 7 may combine one or more processes in order to simplify and/or clarify the method for providing or fabricating a chiplet with trench capacitor. In some implementations, the order of the processes may be changed or modified.

The method provides (at 705) a substrate (e.g., 202). The substrate 202 may be a chiplet substrate. The substrate 202 may include silicon (Si). Stage 1 of FIG. 6A, illustrates and describes an example of providing a chiplet substrate.

The method forms (at 710) a plurality of trenches (e.g., 600) in the substrate (e.g., 202). The plurality of trenches 600 may include a plurality of cavities. The plurality of trenches 600 may include a first trench, a second trench, a third trench, and a fourth trench. The trenches may have different shapes and/or different depths. An etching process may be used to form the plurality of trenches 600. The plurality of trenches 600 may be evenly spaced or have different spacing. Stage 2 of FIG. 6A, illustrates and describes an example of forming trenches.

The method forms (at 715) an oxide layer (e.g., 204) over the plurality of trenches. The oxide layer 204 may be formed over a surface of the substrate 202. A deposition process may be used to form the oxide layer 204 over the surface of the substrate 202 including over and in the plurality of trenches 600. A low-pressure chemical vapor deposition (LPCVD) process may be used to form the oxide layer 204. The oxide layer 204 may take up the shape and/or contour of the plurality of trenches 600. Stage 3 of FIG. 6B, illustrates and describes an example of forming an oxide layer.

The method forms (at 720) a first electrically conductive layer (e.g., 206) over an oxide layer (e.g., 204). The first electrically conductive layer 206 may be formed over the oxide layer 204. The first electrically conductive layer 206 may include polysilicon. A deposition process may be used to form the first electrically conductive layer 206 over the oxide layer 204 including over and in the plurality of trenches 600. For example, a low-pressure chemical vapor deposition (LPCVD) process may be used to form the first electrically conductive layer 206. The first electrically conductive layer 206 may take up the shape and/or the contour of the oxide layer 204 and/or the plurality of trenches 600. Forming the first electrically conductive layer 206 may include doping the first electrically conductive layer 206 with a dopant. Stage 4 of FIG. 6B, illustrates and describes an example of forming a first electrically conductive layer.

The method forms (at 725) a dielectric layer (e.g., 208) over the first electrically conductive layer (e.g., 206). A deposition process may be used to form the dielectric layer 208 over the first electrically conductive layer 206 including over and in the plurality of trenches 600. Stage 5 of FIG. 6C, illustrates and describes an example of forming a dielectric layer.

The method forms (at 730) a second electrically conductive layer (e.g., 210) over the dielectric layer (e.g., 208). The second electrically conductive layer 210 may include polysilicon. A deposition process may be used to form the second electrically conductive layer 210 over the dielectric layer 208 including over and in the plurality of trenches 600. A low-pressure chemical vapor deposition (LPCVD) process may be used to form the second electrically conductive layer 210. The second electrically conductive layer 210 may fill up the plurality of trenches 600. In some implementations, additional portion(s) of the first electrically conductive layer 206 may also be formed (at 730). The additional portion(s) of the first electrically conductive layer 206 may be formed through opening(s) of the dielectric layer 208. The additional portion of the first electrically conductive layer 206 may be used as pad(s) configured to be coupled to solder interconnects. Stage 6 of FIG. 6D, illustrates and describes an example of forming a second electrically conductive layer.

The method forms (at 735) at least one cavity (e.g., 610) in the substrate 202. An etching process and/or a laser process (e.g., laser ablation) may be used to form the at least one cavity 610 that extends through the entire thickness of the substrate 202. Stage 7 of FIG. 6D, illustrates and describes an example of forming at least one cavity in a substrate.

The method forms (at 740) at least one interconnect (e.g., 209) in the cavity (e.g., 610) of the substrate (e.g., 202). In some implementations, a first interconnect (e.g., 292) may be formed over a first surface of the substrate, and a second interconnect (e.g., 294) may be formed over a second surface of the substrate. The first interconnect and the second interconnect may be coupled to the interconnect located in the cavity of the substrate. A plating process may be used to form the interconnects (e.g., 209, 292, 294). Stage 8 of FIG. 6D, illustrates and describes an example forming at least one interconnect in the cavity of a substrate.

### Exemplary Sequence for Fabricating a Package Comprising a Substrate and a Passive Device

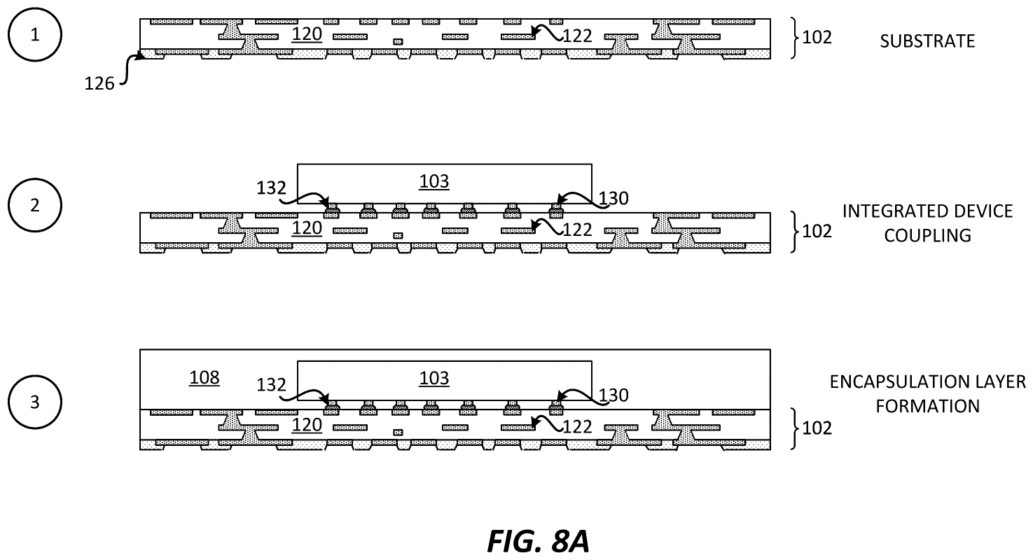

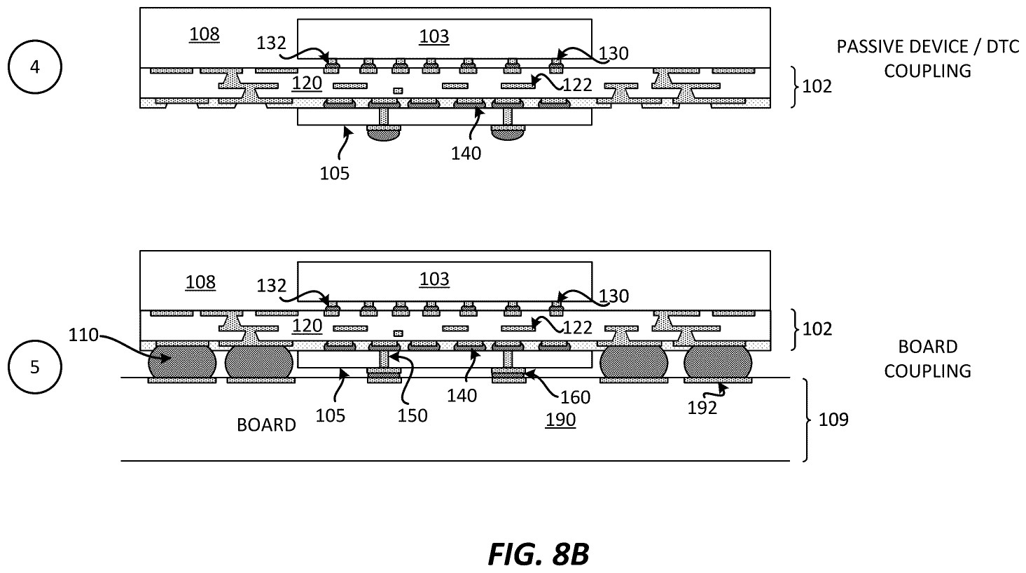

In some implementations, fabricating a package includes several processes. FIGS. 8A-8B illustrate an exemplary sequence for providing or fabricating a package. In some implementations, the sequence of FIGS. 8A-8B may be used to provide or fabricate the package 100. However, the process of FIGS. 8A-8B may be used to fabricate any of the packages described in the disclosure.

It should be noted that the sequence of FIGS. 8A-8B may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

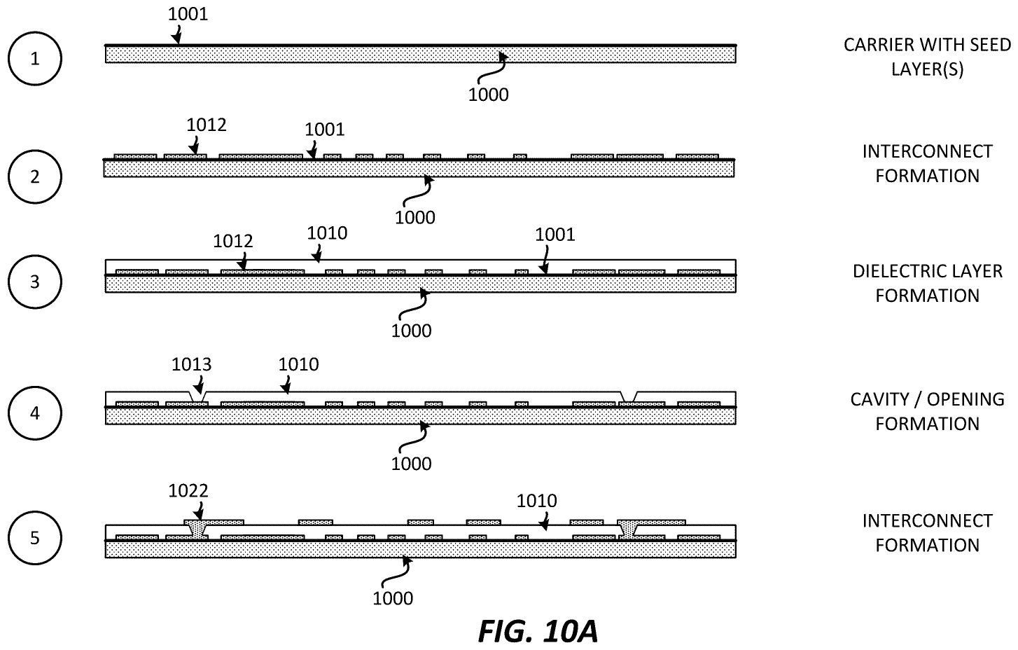

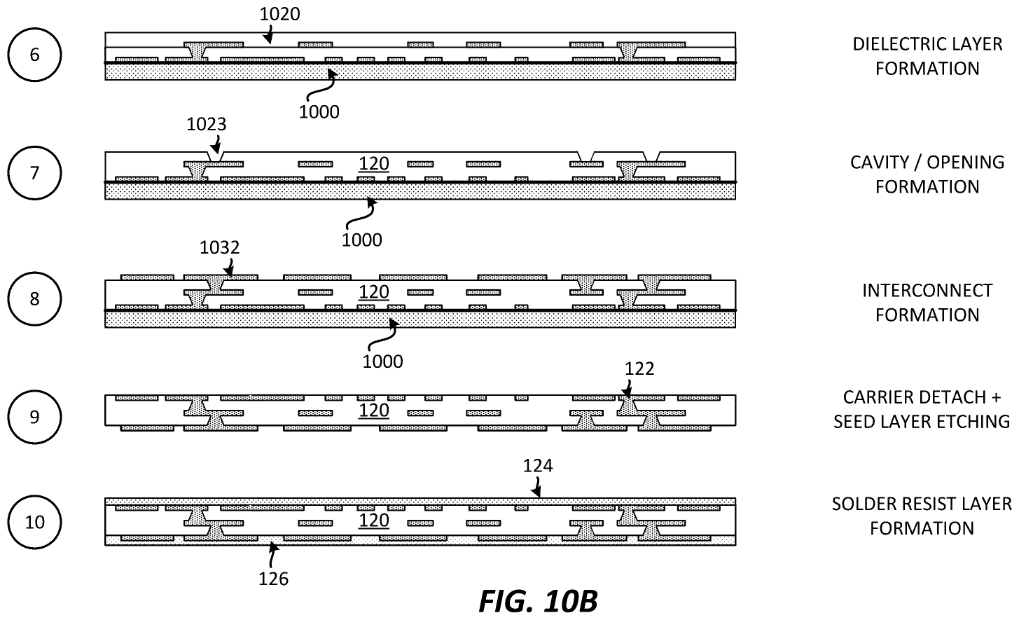

Stage 1, as shown in FIG. 8A, illustrates a state after a substrate 102 is provided. The substrate 102 may be a first substrate. The substrate 102 includes at least one dielectric layer 120, a plurality of interconnects 122 and a solder resist layer 126. The substrate 102 may include a first surface (e.g., top surface) and a second surface (e.g., bottom surface). The substrate 102 may be fabricated using the method as described in FIGS. 10A-10B.

Stage 2 illustrates a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.

Stage 3 illustrates a state after an encapsulation layer 108 is provided and coupled to the substrate 102. The encapsulation layer 108 may at least partially encapsulate the integrated device 103. The encapsulation layer 108 may be coupled to the first surface of the substrate 102. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

Stage 4, as shown in FIG. 8B, illustrates a state after the passive device 105 is coupled to the second surface (e.g., bottom surface) of the substrate 104. The passive device 105 may be coupled to the substrate 104 through the plurality of solder interconnects 140. A solder reflow process may be used to couple the passive device 105 to the substrate 104. The passive device 105 may include a trench capacitor device (e.g., deep trench capacitor device). The passive device 105 may include a plurality of through substrate vias. An example of the passive device 105 is the chiplet 200 of FIG. 2. Stage 4 may illustrate a package 100 that includes a substrate 102 and a passive device 105.

Stage 5 illustrates a state after the package 100 is coupled to the board 109. The package 100 is coupled to the board 109 through a plurality of solder interconnects 110 and through a plurality of solder interconnects 160. For example, the substrate 102 may be coupled to the board 109 through the plurality of solder interconnects 110. The plurality of solder interconnects 110 may be coupled to interconnects of the substrate 102 and board interconnects of the board 109. The passive device 105 may be coupled to the board 109 through the plurality of solder interconnects 160. The plurality of solder interconnects 160 may be coupled to interconnects of the passive device 105 and board interconnects of the board 109.

### Exemplary Flow Diagram of a Method for Fabricating a Package Comprising a Substrate and a Passive Device

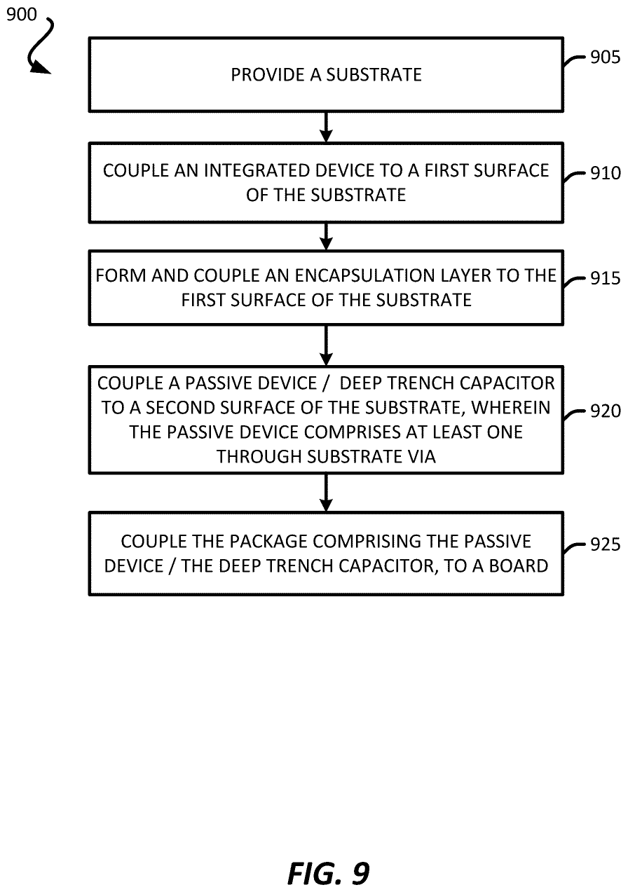

In some implementations, fabricating a package includes several processes. FIG. 9 illustrates an exemplary flow diagram of a method 900 for providing or fabricating a package. In some implementations, the method 900 of FIG. 9 may be used to provide or fabricate the package 100 described in the disclosure. However, the method 900 may be used to provide or fabricate any of the packages described in the disclosure.

It should be noted that the method 900 of FIG. 9 may combine one or more processes in order to simplify and/or clarify the method for providing or fabricating a package. In some implementations, the order of the processes may be changed or modified.

The method provides (at 905) a substrate that includes a plurality of interconnects. Stage 1 of FIG. 8A, illustrates and describes an example of a state after a substrate 102 is provided. The substrate 102 may be a first substrate. The substrate 102 includes at least one dielectric layer 120, a plurality of interconnects 122 and a solder resist layer 126. The substrate 102 may include a first surface (e.g., top surface) and a second surface (e.g., bottom surface). The substrate 102 may be fabricated using the method as described in FIGS. 10A-10B.

The method couples (at 910) an integrated device to a first surface of the substrate. Stage 2 of FIG. 8A, illustrates and describes an example of a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.

The method forms and couples (at 915) an encapsulation layer to the first surface of the substrate. Stage 3 of FIG. 8A, illustrates and describes an example of a state after an encapsulation layer 108 is provided and coupled to the substrate 102. The encapsulation layer 108 may at least partially encapsulate the integrated device 103. The encapsulation layer 108 may be coupled to the first surface of the substrate 102. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

The method couples (at 920) a passive device to a second surface of the substrate. Stage 4 of FIG. 8B, illustrates and describes an example of a state after the passive device 105 is coupled to the second surface (e.g., bottom surface) of the substrate 104. The passive device 105 may be coupled to the substrate 104 through the plurality of solder interconnects 140. A solder reflow process may be used to couple the passive device 105 to the substrate 104. The passive device 105 may include a trench capacitor device (e.g., deep trench capacitor device). Stage 4 of FIG. 8B, may illustrate a package 100 that includes a substrate 102 and a passive device 105.

The method may couple (at 925) the package to a board. Stage 5 of FIG. 8B, illustrates and describes an example of a state after the package 100 is coupled to the board 109. The package 100 is coupled to the board 109 through a plurality of solder interconnects 110 and through a plurality of solder interconnects 160. For example, the substrate 102 may be coupled to the board 109 through the plurality of solder interconnects 110. The plurality of solder interconnects 110 may be coupled to interconnects of the substrate 102 and board interconnects of the board 109. The passive device 105 may be coupled to the board 109 through the plurality of solder interconnects 160. The plurality of solder interconnects 160 may be coupled to interconnects of the passive device 105 and board interconnects of the board 109.

### Exemplary Sequence for Fabricating a Substrate

In some implementations, fabricating a substrate includes several processes. FIGS. 10A-10B illustrate an exemplary sequence for providing or fabricating a substrate. In some implementations, the sequence of FIGS. 10A-10B may be used to provide or fabricate the substrate 102. However, the process of FIGS. 10A-10B may be used to fabricate any of the substrates (e.g., 104) described in the disclosure.

It should be noted that the sequence of FIGS. 10A-10B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 10A, illustrates a state after a carrier 1000 is provided. A seed layer 1001 may be located over the carrier 1000.

Stage 2 illustrates a state after a plurality of interconnects 1012 are formed. The interconnects 1012 may be located over the seed layer 1001. A plating process and etching process may be used to form the plurality of interconnects 1012. The interconnects 1012 may represent at least some of the interconnects from the plurality of interconnects 122.

Stage 3 illustrates a state after a dielectric layer 1010 is formed over the carrier 1000, the seed layer 1001 and the plurality of interconnects 1012. A deposition and/or lamination process may be used to form the dielectric layer 1010. The dielectric layer 1010 may include prepreg and/or polyimide. The dielectric layer 1010 may include a photo-imageable dielectric. However, different implementations may use different materials for the dielectric layer.

Stage 4 illustrates a state after a plurality of cavities 1013 is formed in the dielectric layer 1010. The plurality of cavities 1013 may be formed using an etching process (e.g., photo etching process) or laser process.

Stage 5 illustrates a state after interconnects 1022 are formed in and over the dielectric layer 1010, including in and over the plurality of cavities 1013. For example, a via, pad and/or traces may be formed. A plating process may be used to form the interconnects.

Stage 6, as shown in FIG. 10B, illustrates a state after a dielectric layer 1020 is formed over the dielectric layer 1010 and the plurality of interconnects 1022. A deposition and/or lamination process may be used to form the dielectric layer 1020. The dielectric layer 1020 may include prepreg and/or polyimide. The dielectric layer 1020 may include a photo-imageable dielectric. However, different implementations may use different materials for the dielectric layer.

Stage 7, illustrates a state after a plurality of cavities 1023 is formed in the dielectric layer 120. The dielectric layer 120 may represent the dielectric layer 1010 and/or the dielectric layer 1020. The plurality of cavities 1023 may be formed using an etching process (e.g., photo etching process) or laser process.

Stage 8 illustrates a state after interconnects 1032 are formed in and over the dielectric layer 120, including in and over the plurality of cavities 1023. For example, a via, pad and/or traces may be formed. A plating process may be used to form the interconnects.

Stage 9 illustrates a state after the carrier 1000 is decoupled (e.g., detached, removed, grinded out) from at least one dielectric layer 120 and the seed layer 1001, portions of the seed layer 1001 are removed (e.g., etched out), leaving the substrate 102 that includes at least one dielectric layer 120 and the plurality of interconnects 122. The plurality of interconnects 122 may represent the plurality of interconnects 1012, the plurality of interconnects 1022 and/or the plurality of interconnects 1032.

Stage 10 illustrates a state after the solder resist layer 124 is formed over the first surface of the substrate 102, and after the solder resist layer 126 is formed over the second surface of the substrate 102. A deposition process and/or lamination process may be used to form the solder resist layer 124 and/or the solder resist layer 126. The solder resist layer 124 and/or the solder resist layer 126 may include openings. An etching process may be used to form the openings in the solder resist layer 124 and/or the openings in the solder resist layer 126.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Substrate

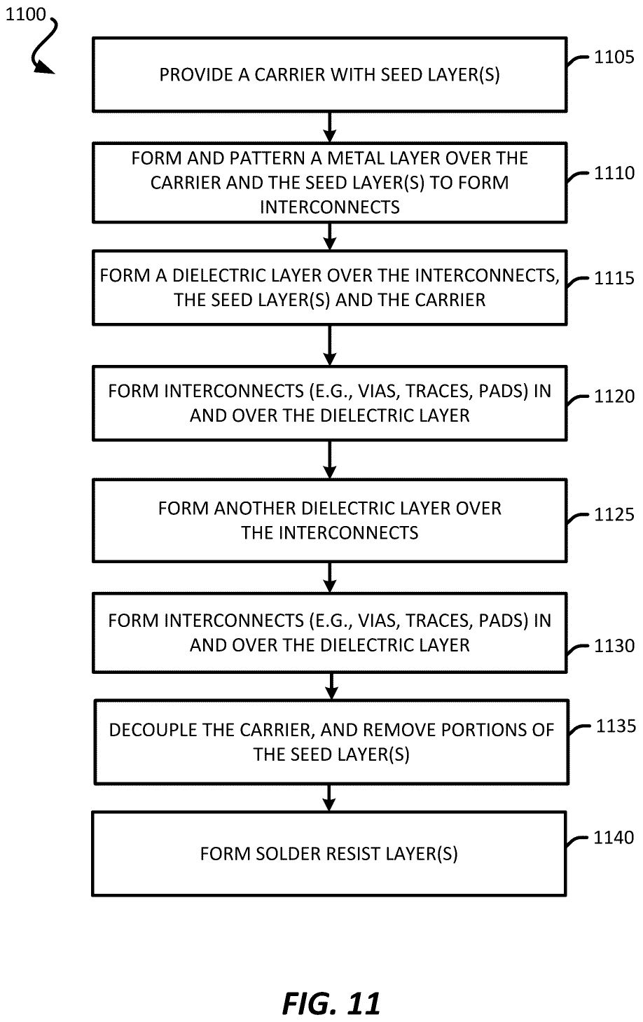

In some implementations, fabricating a substrate includes several processes. FIG. 11 illustrates an exemplary flow diagram of a method 1100 for providing or fabricating a substrate. In some implementations, the method 1100 of FIG. 11 may be used to provide or fabricate the substrate(s) of the disclosure. For example, the method 1100 of FIG. 11 may be used to fabricate the substrate 102.

It should be noted that the method 1100 of FIG. 11 may combine one or more processes in order to simplify and/or clarify the method for providing or fabricating a substrate. In some implementations, the order of the processes may be changed or modified.

The method provides (at 1105) a carrier with a seed layer. Stage 1 of FIG. 10A, illustrates and describes an example of a state after a carrier 1000 is provided. A seed layer 1001 may be located over the carrier 1000.

The method forms and patterns (at 1110) a plurality of interconnects. Stage 2 of FIG. 10A, illustrates and describes an example of a state after a plurality of interconnects 1012 are formed. The interconnects 1012 may be located over the seed layer 1001. A plating process and etching process may be used to form the plurality of interconnects 1012. The interconnects 1012 may represent at least some of the interconnects from the plurality of interconnects 122.

The method forms (at 1115) a dielectric layer. Stage 3 of FIG. 10A, illustrates and describes an example of a state after a dielectric layer 1010 is formed over the carrier 1000, the seed layer 1001 and the plurality of interconnects 1012. A deposition and/or lamination process may be used to form the dielectric layer 1010. The dielectric layer 1010 may include prepreg and/or polyimide. The dielectric layer 1010 may include a photo-imageable dielectric. However, different implementations may use different materials for the dielectric layer.

The method forms (at 1120) a plurality of interconnects. Forming a plurality of interconnects may including forming a plurality of cavities in a dielectric layer and a performing a plating process. Stage 4 of FIG. 10A, illustrates and describes an example of a state after a plurality of cavities 1013 is formed in the dielectric layer 1010. The plurality of cavities 1013 may be formed using an etching process (e.g., photo etching process) or laser process.

Stage 5 of FIG. 10A, illustrates and describes an example of a state after interconnects 1022 are formed in and over the dielectric layer 1010, including in and over the plurality of cavities 1013. For example, a via, pad and/or traces may be formed. A plating process may be used to form the interconnects.

The method forms (at 1125) another dielectric layer. Stage 6 of FIG. 10B, illustrates and describes an example of a state after a dielectric layer 1020 is formed over the dielectric layer 1010 and the plurality of interconnects 1022. A deposition and/or lamination process may be used to form the dielectric layer 1020. The dielectric layer 1020 may include prepreg and/or polyimide. The dielectric layer 1020 may include a photo-imageable dielectric. However, different implementations may use different materials for the dielectric layer.

The method forms (at 1130) a plurality of interconnects. Forming a plurality of interconnects may including forming a plurality of cavities in a dielectric layer and a performing a plating process. Stage 7 of FIG. 10B, illustrates and describes an example of a state after a plurality of cavities 1023 is formed in the dielectric layer 120. The dielectric layer 120 may represent the dielectric layer 1010 and/or the dielectric layer 1020. The plurality of cavities 1023 may be formed using an etching process (e.g., photo etching process) or laser process.

Stage 8 of FIG. 10B, illustrates and describes an example of a state after interconnects 1032 are formed in and over the dielectric layer 120, including in and over the plurality of cavities 1023. For example, a via, pad and/or traces may be formed. A plating process may be used to form the interconnects.

The method decouples (at 1135) a carrier. Stage 9 of FIG. 10B, illustrates and describes an example of a state after the carrier 1000 is decoupled (e.g., detached, removed, grinded out) from at least one dielectric layer 120 and the seed layer 1001, portions of the seed layer 1001 are removed (e.g., etched out), leaving the substrate 102 that includes at least one dielectric layer 120 and the plurality of interconnects 122. The plurality of interconnects 122 may represent the plurality of interconnects 1012, the plurality of interconnects 1022 and/or the plurality of interconnects 1032.

The method forms (at 1140) solder resist layers. Stage 10 of FIG. 10B, illustrates and describes an example of a state after the solder resist layer 124 is formed over the first surface of the substrate 102, and after the solder resist layer 126 is formed over the second surface of the substrate 102. A deposition process and/or lamination process may be used to form the solder resist layer 124 and/or the solder resist layer 126. An etching process may be used to form the openings and/or the openings in the solder resist layer 124 and/or the solder resist layer 126.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

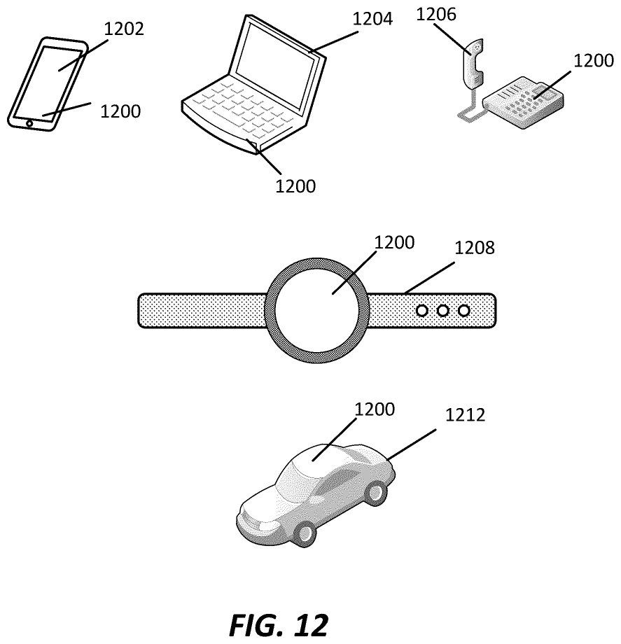

FIG. 12 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1202, a laptop computer device 1204, a fixed location terminal device 1206, a wearable device 1208, or automotive vehicle 1212 may include a device 1200 as described herein. The device 1200 may be, for example, any of the devices and/or integrated circuit (IC) packages described herein. The devices 1202, 1204, 1206 and 1208 and the vehicle 1210 illustrated in FIG. 12 are merely exemplary. Other electronic devices may also feature the device 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-5, 6A-6D, 7, 8A-8B, 9, 10A-10B, and 11-12 may be rearranged and/or combined into a single component, process, feature or function or embodied in several components, processes, or functions. Additional elements, components, processes, and/or functions may also be added without departing from the disclosure. It should also be noted FIGS. 1-5, 6A-6D, 7, 8A-8B, 9, 10A-10B, and 11-12 and its corresponding description in the present disclosure is not limited to dies and/or ICs. In some implementations, FIGS. 1-5, 6A-6D, 7, 8A-8B, 9, 10A-10B, and 11-12 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a substrate comprising a first surface and a second surface, wherein the substrate further comprises: at least one dielectric layer; and a plurality of interconnects; an integrated device coupled to the first surface of the substrate through at least a first plurality of solder interconnects; and a passive device coupled to the second surface of the substrate through at least a second plurality of solder interconnects, wherein the passive device comprises at least one through substrate via.

Aspect 2: The package of aspect 1, wherein the passive device comprises a trench capacitor device.

Aspect 3: The package of aspect 2, wherein the trench capacitor device comprises a passive device substrate, and wherein the at least one through substrate via extends through the passive device substrate.

Aspect 4: The package of aspect 1, wherein the passive device comprises a plurality of trench capacitors.

Aspect 5: The package of aspects 1 through 4, wherein the substrate is coupled to a board through a third plurality of solder interconnects, and wherein the passive device is coupled to the board through a fourth plurality of solder interconnects.

Aspect 6: The package of aspect 5, wherein an electrical path between the integrated device and the board comprises (i) a solder interconnect from the first plurality of solder interconnects, (ii) at least one interconnect from the plurality of interconnects of the substrate, (iii) a solder interconnect from the second plurality of solder interconnects, (iv) at least one through substrate via from the passive device, and/or (v) a solder interconnect from the fourth plurality of solder interconnects.

Aspect 7: The package of aspect 5, wherein an electrical path between the integrated device and the board comprises (i) a solder interconnect from the first plurality of solder interconnects, (ii) at least one interconnect from the plurality of interconnects of the substrate, and/or (iii) a solder interconnect from the fourth plurality of solder interconnects.

Aspect 8: The package of aspect 5, wherein a first electrical path between the integrated device and the board comprises (i) a solder interconnect from the first plurality of solder interconnects, (ii) at least one interconnect from the plurality of interconnects of the substrate, (iii) a solder interconnect from the second plurality of solder interconnects, (iv) at least one through substrate via from the passive device, and/or (v) a solder interconnect from the fourth plurality of solder interconnects, and wherein a second electrical path between the integrated device and the board comprises (i) a solder interconnect from the first plurality of solder interconnects, (ii) at least one interconnect from the plurality of interconnects of the substrate, and/or (iii) a solder interconnect from the fourth plurality of solder interconnects.

Aspect 9: The package of aspects 1 through 8, wherein the passive device is part of a power distribution network for the integrated device.

Aspect 10: The package of aspect 1, wherein the passive device comprises: a passive device substrate; a plurality of trench capacitors located at least partially in the passive device substrate; and a first metallization portion located on a first surface of the passive device substrate, wherein the at least one through substrate via extends through the passive device substrate, and wherein the at least one through substrate via is coupled to the first metallization portion.

Aspect 11: A method for fabricating a package. The method provides a substrate comprising a first surface and a second surface, wherein the substrate further comprises: at least one dielectric layer; and a plurality of interconnects. The method couples an integrated device to the first surface of the substrate through at least a first plurality of solder interconnects. The method couples a passive device to the second surface of the substrate through at least a second plurality of solder interconnects, wherein the passive device comprises at least one through substrate via.

Aspect 12: The method of aspect 11, wherein the passive device comprises a trench capacitor device.

Aspect 13: The method of aspect 12, wherein the trench capacitor device comprises a passive device substrate, and wherein the at least one through substrate via extends through the passive device substrate.

Aspect 14: The method of aspect 11, wherein the passive device comprises a plurality of trench capacitors.

Aspect 15: The method of aspect 11, wherein the substrate is coupled to a board through a third plurality of solder interconnects, and wherein the passive device is coupled to the board through a fourth plurality of solder interconnects.

Aspect 16: The method of aspect 15, wherein an electrical path between the integrated device and the board comprises (i) a solder interconnect from the first plurality of solder interconnects, (ii) at least one interconnect from the plurality of interconnects of the substrate, (iii) a solder interconnect from the second plurality of solder interconnects, (iv) at least one through substrate via from the passive device, and/or (v) a solder interconnect from the fourth plurality of solder interconnects.

Aspect 17: The method of aspect 15, wherein an electrical path between the integrated device and the board comprises (i) a solder interconnect from the first plurality of solder interconnects, (ii) at least one interconnect from the plurality of interconnects of the substrate, and/or (iii) a solder interconnect from the fourth plurality of solder interconnects.

Aspect 18: The method of aspect 15, wherein a first electrical path between the integrated device and the board comprises (i) a solder interconnect from the first plurality of solder interconnects, (ii) at least one interconnect from the plurality of interconnects of the substrate, (iii) a solder interconnect from the second plurality of solder interconnects, (iv) at least one through substrate via from the passive device, and/or (v) a solder interconnect from the fourth plurality of solder interconnects, and wherein a second electrical path between the integrated device and the board comprises (i) a solder interconnect from the first plurality of solder interconnects, (ii) at least one interconnect from the plurality of interconnects of the substrate, and/or (iii) a solder interconnect from the fourth plurality of solder interconnects.

Aspect 19: The method of aspects 11 through 18, wherein the passive device is part of a power distribution network for the integrated device.

Aspect 20: The method of aspect 11, wherein the passive device comprises: a passive device substrate; a plurality of trench capacitors located at least partially in the passive device substrate; and a first metallization portion located on a first surface of the passive device substrate, wherein the at least one through substrate via extends through the passive device substrate, and wherein the at least one through substrate via is coupled to the first metallization portion.

Aspect 21: The package of aspects 1 through 10, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate comprising a first surface and a second surface, wherein the substrate further comprises:
at least one dielectric layer; and
a plurality of interconnects;
an integrated device coupled to the first surface of the substrate through at least a first plurality of solder interconnects; and
a passive device coupled to the second surface of the substrate through at least a second plurality of solder interconnects, wherein the passive device comprises at least one through substrate via.

2. The package of claim 1, wherein the passive device comprises a trench capacitor device.

3. The package of claim 2,
wherein the trench capacitor device comprises a passive device substrate, and
wherein the at least one through substrate via extends through the passive device substrate.

4. The package of claim 1, wherein the passive device comprises a plurality of trench capacitors.

5. The package of claim 1,
wherein the substrate is coupled to a board through a third plurality of solder interconnects, and
wherein the passive device is coupled to the board through a fourth plurality of solder interconnects.

6. The package of claim 5, wherein an electrical path between the integrated device and the board comprises (i) a solder interconnect from the first plurality of solder interconnects, (ii) at least one interconnect from the plurality of interconnects of the substrate, (iii) a solder interconnect from the second plurality of solder interconnects, (iv) at least one through substrate via from the passive device, and/or (v) a solder interconnect from the fourth plurality of solder interconnects.

7. The package of claim 5, wherein an electrical path between the integrated device and the board comprises (i) a solder interconnect from the first plurality of solder interconnects, (ii) at least one interconnect from the plurality of interconnects of the substrate, and/or (iii) a solder interconnect from the fourth plurality of solder interconnects.

8. The package of claim 5,
wherein a first electrical path between the integrated device and the board comprises (i) a solder interconnect from the first plurality of solder interconnects, (ii) at least one interconnect from the plurality of interconnects of the substrate, (iii) a solder interconnect from the second plurality of solder interconnects, (iv) at least one through substrate via from the passive device, and/or (v) a solder interconnect from the fourth plurality of solder interconnects, and
wherein a second electrical path between the integrated device and the board comprises (i) a solder interconnect from the first plurality of solder interconnects, (ii) at least one interconnect from the plurality of interconnects of the substrate, and/or (iii) a solder interconnect from the fourth plurality of solder interconnects.

9. The package of claim 1, wherein the passive device is part of a power distribution network for the integrated device.

10. The package of claim 1,
wherein the passive device comprises:
a passive device substrate;
a plurality of trench capacitors located at least partially in the passive device substrate; and
a first metallization portion located on a first surface of the passive device substrate,
wherein the at least one through substrate via extends through the passive device substrate, and
wherein the at least one through substrate via is coupled to the first metallization portion.

11. A method for fabricating a package, comprising:
providing a substrate comprising a first surface and a second surface, wherein the substrate further comprises:
at least one dielectric layer; and
a plurality of interconnects;
coupling an integrated device to the first surface of the substrate through at least a first plurality of solder interconnects; and
coupling a passive device to the second surface of the substrate through at least a second plurality of solder interconnects, wherein the passive device comprises at least one through substrate via.

12. The method of claim 11, wherein the passive device comprises a trench capacitor device.

13. The method of claim 12,
wherein the trench capacitor device comprises a passive device substrate, and
wherein the at least one through substrate via extends through the passive device substrate.

14. The method of claim 11, wherein the passive device comprises a plurality of trench capacitors.

15. The method of claim 11,
wherein the substrate is coupled to a board through a third plurality of solder interconnects, and
wherein the passive device is coupled to the board through a fourth plurality of solder interconnects.

16. The method of claim 15, wherein an electrical path between the integrated device and the board comprises (i) a solder interconnect from the first plurality of solder interconnects, (ii) at least one interconnect from the plurality of interconnects of the substrate, (iii) a solder interconnect from the second plurality of solder interconnects, (iv) at least one through substrate via from the passive device, and/or (v) a solder interconnect from the fourth plurality of solder interconnects.

17. The method of claim 15, wherein an electrical path between the integrated device and the board comprises (i) a solder interconnect from the first plurality of solder interconnects, (ii) at least one interconnect from the plurality of interconnects of the substrate, and/or (iii) a solder interconnect from the fourth plurality of solder interconnects.

18. The method of claim 15,
wherein a first electrical path between the integrated device and the board comprises (i) a solder interconnect from the first plurality of solder interconnects, (ii) at least one interconnect from the plurality of interconnects of the substrate, (iii) a solder interconnect from the second plurality of solder interconnects, (iv) at least one through substrate via from the passive device, and/or (v) a solder interconnect from the fourth plurality of solder interconnects, and
wherein a second electrical path between the integrated device and the board comprises (i) a solder interconnect from the first plurality of solder interconnects, (ii) at least one interconnect from the plurality of interconnects of the substrate, and/or (iii) a solder interconnect from the fourth plurality of solder interconnects.

19. The method of claim 11, wherein the passive device is part of a power distribution network for the integrated device.

20. The method of claim 11,
wherein the passive device comprises:
a passive device substrate;
a plurality of trench capacitors located at least partially in the passive device substrate; and
a first metallization portion located on a first surface of the passive device substrate,
wherein the at least one through substrate via extends through the passive device substrate, and
wherein the at least one through substrate via is coupled to the first metallization portion.
